(19) United States
(12) Patent Application Publication
(10) Pub. No.: US 2003/0189962 A1
(43) Pub. Date: Oct. 9, 2003

(54) Stabile mode broad stripe semiconductor diode laser

(76) Inventor: James Harrison, Morgan Hill, CA (US)

Correspondence Address: Howard R. Popper, Ste. #35, 4436 E. Camelback Rd., Phoenix, AZ, 85018-2833, US

(21) Appl. No.: 10/117,969

(22) Filed: Apr. 6, 2002

(51) Int. Cl. H01S 5/00

(52) U.S. Cl. 372/49

(57) ABSTRACT

A wide stripe laser having generally planar facets has most of its output facet coated for maximum transmission so that it provides substantially no feedback into the cavity. A reflective coating is used on only a very small segment of the output facet so that feedback is provided only for those rays that are incident nearly normal to the output facet. Such near-normal rays are reflected back into the cavity to initiate oscillation in the cavity's gain region. The rear surface of the cavity is coated to re-radiate the rays reflected from the small segment of the output facet but now these rays pass through the maximum transmission portion of the output facet.

### FIELD OF THE INVENTION

This invention relates to semiconductor devices and, more particularly, to high power laser diodes.

### BACKGROUND OF THE INVENTION

The gain region of a conventional double-heterostructure diode laser is defined by a stripe electrode or by index guiding. To minimize lasing in other than the desired mode, the width of the stripe is often made quite narrow. Unfortunately, this can result in excessive power density, especially at a facet resulting catastrophic damage. As a consequence many lasers are “broad stripe” lasers that have a stripe greater than 0.01 mm and which have a tendency to lase in more than a single mode. To overcome these problems it has been proposed as, for example, in U.S. Pat. No. 4,942,585 (1990), to employ a tapered stripe having an elongated active gain medium with a high reflectivity mirror at the narrow end of the gain stripe and a low reflectivity mirror end at the wide end of the gain stripe. The master oscillator, power amplifier (MOPA) structure is an alternative in which the waveguide is divided between an oscillator section and an amplifier section. Typically, as in U.S. Pat. No. 6,307,873 (2001), the dimensions of the waveguide are constant along the length of the oscillator section but increase monotonically parallel to the junction plane in the amplifier section toward the output facet. Various filters may be employed between the oscillator and amplifier sections. MOPA structures are particularly interesting for power scaling as the narrow stripe oscillator segment can be designed to provide relatively good beam quality, which can largely be preserved as the beam traverses the amplifier segment. Structures, sometimes referred to as spoilers, are often included near the oscillator/amplifier interface to prevent oscillation within the amplifier segment which would result in multiple modes. Another technique that has been used in the prior art is shown in U.S. Pat. No. 4,739,508 (1998) and in U.S. Pat. No. 5,179,568 which employ curved facets. In one version, a concave reflective facet is at one end of the gain region and, at the other end of the gain region, a facet that has both a reflective curved portion and a non-reflective planar portion so as to create an unstable resonator. Unfortunately, providing concave and part convex shaped facets presents a difficult manufacturing problem. It would be of great advantage to provide an unstable resonator structure which could employ generally planar facets.

### SUMMARY OF THE INVENTION

In accordance with the principles of the illustrative embodiment, a wide stripe laser having generally planar facets is employed but in which most of the output facet of the resonator cavity is coated for maximum, or relatively high, transmission so that it provides substantially no feedback into the cavity. A reflective coating is used on only a very small segment of the output facet so that feedback is provided only for those rays that are incident nearly normal to the output facet. Such near-normal rays are reflected back into the cavity to initiate oscillation in the cavity's gain region, while the reflection of rays normally associated with high-order spatial modes remains insufficient for the higher order modes to achieve threshold for oscillation. The rear surface of the cavity is coated to re-radiate the rays reflected from the small segment of the output facet but now these rays pass through the maximum transmission portion of the output facet resulting in a higher brightness output beam than that which would be achieved without the segmented facet coating. Whereas a conventional narrow stripe laser concentrates the optical density in a small region of the output facet leading to catastrophic failure if the drive current is increased too far, the embodiment of the invention distributes the output flux of the laser over almost the entire output. Since the area available for output flux is greatly increased over that provided by a conventional narrow gain stripe region, the greater effective output area provides a way to achieve greater output power and/or higher brightness at a given output power without causing catastrophic failure. Moreover, the rays now appear to radiate from a more concentrated point source within the cavity so that they can more easily be focused by corrective lenses.

### BRIEF DESCRIPTION OF THE DRAWING

The foregoing and other features of the invention may become more apparent from a reading of the ensuing description together with the drawing, in which:

FIG. 1 shows a conventional broad stripe laser;

FIG. 2 shows prior art MOPA semiconductor laser; and

FIG. 3 shows an illustrative embodiment of a broad stripe semiconductor device according to the invention; and

FIG. 4 schematically illustrates in greater detail the radiation emitted by the embodiment of FIG. 3.

### DESCRIPTION

Referring now to FIG. 1, a conventional broad stripe heterostructure semiconductor laser diode is comprised of an active layer 13 sandwiched between optical confinement and cladding layers (not shown) built upon a substrate 10. Parallel back and front facets 15, 16 are cleaved and the distance between the facets largely determines the cavity 14 length for lasing action. Basically, a p-n semiconductor junction exits at the active layer 13. When the junction is forward-biased by applying a sufficient voltage level between the conductive surface stripe 12 and substrate 10, a threshold is exceeded so that lasing action takes place within active layer 13 that is in the “shadow” (shown dotted) of stripe 12. The rear fact 16 provides reflection and the output facet 15 may also be coated at 20 to provide sufficient reflectivity to sustain oscillation that is principally determined by the length of cavity 14 between the facets. The output 15 is broad enough that optical density is not high enough under normal drive currents to promote catastrophic optical damage. However the breadth of cavity 14 is such as to allow undesirable multimode oscillations.

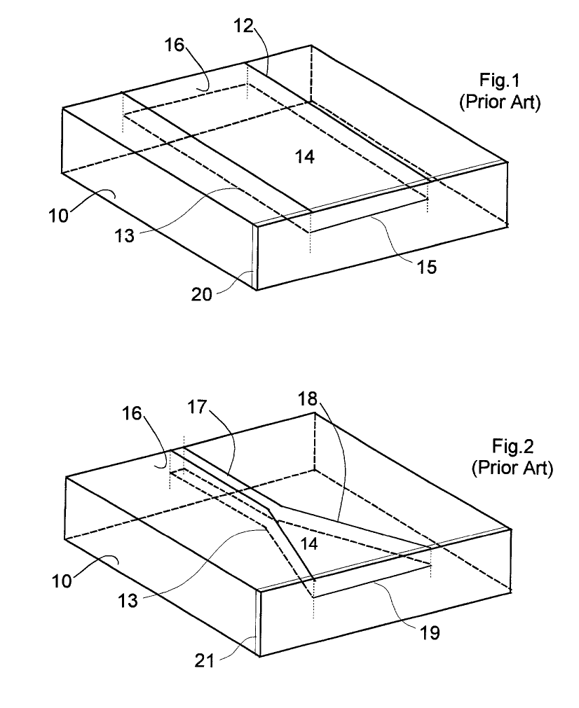

In FIG. 2 multimode oscillations are inhibited in the MOPA construction by providing a narrow surface stripe 17 and by using a grating (not shown) to provide distributed-feedback instead of using the reflective surface 15 of FIG. 1. The narrow surface metallic stripe 17 is followed by a tapered-stripe power amplifier region 18 which broadens toward the output facet 19. As in FIG. 1, lasing action takes place within active layer 13 that is in the “shadow” (shown dotted) of stripes 17 and 18. Output facet 19 is provided with an anti-reflective coated 21 to inhibit reflection in the amplifier region.

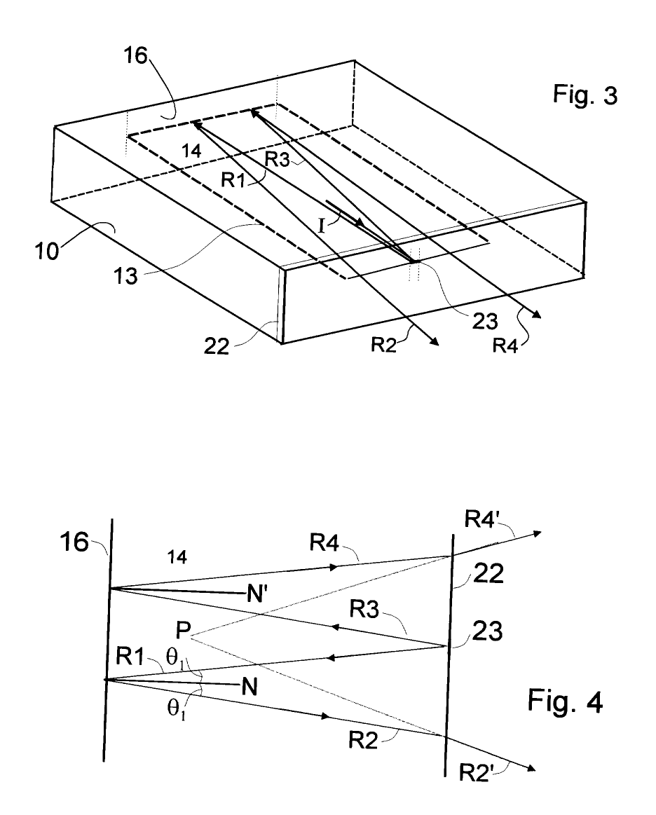

Referring now to FIG. 3, a laser construction according to the present invention is shown. Once again, as in FIG. 1, a broad surface stripe (not shown) is employed. The “shadow” of this broad stripe defines the active layer 13 (shown dotted). Instead of coating the entire surface of the emitting facet (as 19 in FIG. 2) with an anti-reflective coating 21, or of coating the output facet (as 15 in FIG. 1) with a reflective coating 20, a minimal segment 23 of the output facet of FIG. 3 is coated with a reflective coating while the remainder of the output facet has an anti-reflective, or otherwise lower reflectivity, coating 22 applied to it. In this way, only rays such as ray I that are incident nearly normal to the output facet are reflected back into cavity 14 as ray R1. The ray so reflected from portion 23 is re-reflected at rear facet 16 and again passes through the gain region 13 increasing in strength and passing out of the remaining portion of the output facet as ray R2. In this way the power output of the laser may be scaled upwards but the power density at the output facet is not so high as to cause catastrophic optical damage of the output facet.

The output facet may be coated in this way by, for example, applying a first dielectric film 22 having high transmission (highly anti-reflective) characteristics over its entire surface. Then, a second coating 23 is applied which has minimum transmission characteristics, i.e., which is highly reflective, over only the smallest practicable area of the output facet needed to initiate Fabry-Perot oscillation in active layer 13.

FIG. 4 shows in greater detail the radiation emitted by the embodiment of FIG. 3. Ray R1 is reflected from segment 23 of the output facet and is incident upon the rear surface 16 of the cavity at angle θ to normal N. The ray is re-reflected at surface 16 as ray R2 at an equal angle θ to normal N. At the output facet refraction bends the ray so that it emerges as ray R2′. A similar series of events occurs with respect to ray R3 impinging upon reflective segment 23 and this ray emerges from emitting surface 22 as ray R4′. Rays R2′ and R4′ may be extended backward in the classical manner of ray tracing to their point of apparent origin P within cavity 14. Rays emerging from a common point, though diverging, are spatially coherent and can now more easily be focused by conventional corrective lenses (not shown). Accordingly, the use of a small reflective segment 23 on the output facet leads to a more spatially coherent “point” source of radiation than can be generated by a conventional broad stripe laser which has the tendency to generate multiple modes of radiation, commonly referred to as high-order spatial modes. The more spatially coherent source of radiation leads to a brighter, broad stripe laser.

What has been described is deemed to be illustrative of the principles of the invention. Further and other modifications, such as providing the output facet with a graded-reflectivity coating or one whose reflectivity exhibits a super-Gaussian distribution, or a dotted distribution of reflective segments may be used. The coatings may be applied to multiple devices stacked in a coating chamber in which the segmented, low-transmission coating portion(s) would be applied to many devices at once through a slit-type mask. Ink-jet-style coating is an alternative coating technology that is particularly well suited to this invention. Other modifications will be apparent to those skilled in the art and may be made without, however, departing from the spirit and scope of the invention.

What is claimed is:

1. A semiconductor solid state laser having a resonating cavity with a gain region therein, a rear facet and an emitting facet, said laser having a reflective first coating on said rear facet, said emitting facet having thereon a highly transmissive coating over a major portion of said facet which corresponds to said gain region, the remaining minor portion of said emitting facet having thereon a low transmissive and more reflective coating.

2. A laser as in claim 1 wherein said more reflective coating reflects into said cavity principally only those rays arriving at nearly normal angle to said output facet.

3. A laser as in claim 1 wherein said output facet is provided with a coating whose transmission varies from low transmission at the center of said output facet to high transmission toward the edges of said facet.

4. A broad stripe semiconductor laser for emitting spatially coherent radiation comprising a cavity having at opposite ends thereof a substantially reflective facet and an output facet, said output facet exhibiting a substantial variation in reflectivity.

5. A broad stripe semiconductor laser according to claim 4 wherein said spatially coherent radiation is substantially closer in brightness to the brightness of a diffraction limited source than the radiation from an output facet with uniform reflectivity.

6. A broad stripe semiconductor laser according to claim 4, said output facet having a major portion thereof exhibiting a highly transmissive surface and a smaller central portion exhibiting a more highly reflective surface portion, said spatially coherent radiation appearing to radiate from a point source located within said laser cavity.
